(19) United States
(12) Patent Application Publication
(10) Pub. No.: US 2026/0168093 A1
(43) Pub. Date: Jun. 18, 2026

(54) ENHANCED ALD FILM GROWTH IN TWO-ZONE CHAMBER

(71) Applicant: ASM IP Holding B.V., Almere (NL)

(72) Inventor: Tommi Paavo Tynell, Espoo (FI)

(21) Appl. No.: 19/414,456

(22) Filed: Dec. 10, 2025

Related U.S. Application Data
(60) Provisional application No. 63/734,085, filed on Dec. 14, 2024.

(51) Int. Cl. C23C 16/455; C23C 16/44; H10P 14/60; H10P 14/69; H10P 14/692

(52) U.S. Cl. CPC C23C 16/45548; C23C 16/4408; C23C 16/45542; H10P 14/6336; H10P 14/6339; H10P 14/6689; H10P 14/6905; H10P 14/6922

(57) ABSTRACT

A method for forming a film on a surface of a substrate is provided. The method including: introducing a substrate in a lower chamber of a reaction chamber, wherein the reaction chamber is separated into an upper chamber and the lower chamber using an ion trap; introducing a first plasma into the upper chamber; introducing a precursor into the reaction chamber and radicalizing the precursor using the first plasma; introducing a reactant into the reaction chamber; introducing a second plasma into the upper chamber to radicalize the reactant.

### CROSS-REFERENCE TO RELATED APPLICATIONS

This application claims priority to U.S. Provisional Patent Application Ser. No. 63/734,085 filed Dec. 14, 2024 and titled ENHANCED ALD FILM GROWTH IN TWO-ZONE CHAMBER, the disclosure of which is hereby incorporated by reference in its entirety.

### BACKGROUND OF THE INVENTION

### Field of the Invention

The present invention relates methods and systems for enhanced ALD film growth in a deposition chamber with two plasma zones, and, in particular, to methods and systems for a partial breakdown of a precursor for enhanced ALD film growth in a two-zone chamber.

### Description of the Related Art

Fabricating modern semiconductor devices requires the accurate deposition of materials with carefully controlled thicknesses and compositions. Ideally, the desired material compositions could be deposited directly in a single-step process, but often this is not feasible and it becomes necessary to deposit a material layer and then convert it into a layer with the desired elemental composition and properties. For instance, SiON can be made by exposing SiO2 layers to a N2 plasma, because the nitrogen ions and radicals are not reactive enough to remove all the oxygen from the film layer. However, carbon-containing nitride films such as SiCN or SiOCN present more of a problem, since any carbon present in the precursor molecules or the growing film is readily removed by nitrogen or oxygen plasma. Using a CVD process with a precursor chemical containing the desired elements would be an option, but this would lead to issues with film conformality as well as controlling the composition. There is an alternative processing scheme that can be used to enhance the useability of CVD precursors, in which the precursors are exposed to a low-power plasma that partially breaks down the molecules to create more reactive species that are more likely to stick to the substrate surface. This so-called precursor radicalization approach makes CVD precursors available to ALD processing, and it requires a way to expose the precursor flow to direct plasma without affecting the substrate.

Plasma-enhanced atomic layer deposition (PEALD) is a widely used deposition method where plasma is used to create energetic ions and reactive radicals that can greatly benefit the deposition process. However, due to the inherently anisotropic nature of the ion flux on the substrate, PEALD processes often experience issues with conformality of the deposited film. To counter this, radical-enhanced ALD (REALD) was developed as a variant of PEALD in which the ions formed in the plasma sheath are not allowed to reach the substrate and film growth relies only on the reactive radicals in the plasma. This approach leads to a process with characteristics between PEALD and thermal ALD, and it can be very useful especially for applications requiring high levels of conformality. Some applications, however, would benefit from the possibility of using both direct plasma processing and radical exposure in the same process.

### BRIEF SUMMARY OF THE INVENTION

An embodiment of the present invention provides a method for forming a film on a surface of a substrate. The method includes introducing a substrate into the lower chamber of a reaction chamber, wherein the reaction chamber is separated into an upper chamber and a lower chamber using an ion trap. The method includes introducing a first plasma into the upper chamber. The method includes introducing a precursor into the reaction chamber and radicalizing the precursor using the first plasma. The method includes introducing a reactant into the reaction chamber. The method includes introducing a second plasma into the upper chamber to radicalize the reactant.

In some embodiments, the precursor comprises a silazane. In some embodiments, the ion trap is grounded. In some embodiments, the precursor and the reactant are introduced into the reaction chamber via a showerhead. The showerhead is connected to an RF generator to generate the first plasma and the second plasma. In some embodiments, the first plasma and the second plasma cause self-limiting thin film growth. In some embodiments, the method further includes a purge step after introducing a precursor into the reaction chamber, and after introducing a second plasma into the upper chamber. In some embodiments, the RF power of the first plasma is lower than the RF power of the second plasma. In some embodiments, the RF power of the first plasma is lower than 100 W, and the RF power of the second plasma is higher than 50 W.

An embodiment of the present invention provides a method for forming a film on a surface of a substrate. The method includes providing a reaction chamber having an upper chamber and a lower chamber separated by an ion trap. The method includes introducing a substrate into the lower chamber. The method includes introducing a precursor into the reaction chamber and radicalizing the precursor using a first plasma in the upper chamber to form a radicalized precursor. The method includes introducing a reactant into the reaction chamber and generating a second plasma in the lower chamber to break down the reactant and expose the substrate to ions and other plasma species. The RF power of the second plasma is higher than the RF power of the first plasma.

In some embodiments, the precursor comprises a silazane. In some embodiments, the method further includes: purging the reaction chamber between the steps of introducing a precursor and introducing a reactant. In some embodiments, the method further includes: repeating the step of providing a precursor and the step of providing a reactant. In some embodiments, the precursor and the reactant are introduced into the reaction chamber via a showerhead, and the showerhead is connected to a first RF generator to generate the first plasma. The substrate is placed on a susceptor, and the susceptor is connected to a second RF generator to generate the second plasma. In some embodiments, the RF power of the first plasma is lower than 100 W, and the RF power of the second plasma is lower than 1,500 W. In some embodiments, the reactant including at least one of hydrogen, nitrogen, oxygen. In some embodiments, the RF power of the second plasma is higher than the RF power of the first plasma.

An embodiment of the present invention provides a semiconductor processing apparatus, including a reaction chamber, a showerhead, a susceptor, an ion trap, a precursor source, a reactant source, a first RF generator. The showerhead is located at the upper portion of the reaction chamber. The susceptor is located at the lower portion of the reaction chamber and supports a substrate. The ion trap is disposed between the showerhead and the susceptor. The precursor source introduces a precursor into the reaction chamber via the showerhead. The reactant source introduces a reactant into the reaction chamber via the showerhead. The first RF generator is connected to the showerhead and generating a first plasma between the showerhead and the ion trap via the showerhead.

In some embodiments, the ion trap is a mesh plate, and the mesh plate is grounded. In some embodiments, the semiconductor processing apparatus further includes a controller. The controller is configured to ignite the first plasma between the showerhead and the ion trap. The controller is configured to introduce the precursor into the reaction chamber. The controller is configured to purge the reaction chamber. The controller is configured to introduce the reactant into the reaction chamber. The controller is configured to ignite the second plasma between the ion trap and the susceptor. The controller is configured to purge the reaction chamber. In some embodiments, the second RF generator is connected to the susceptor and generating a second plasma between the ion trap and the susceptor via the susceptor. In some embodiments, the first RF generator and the second RF generator are separate RF generators.

### BRIEF DESCRIPTION OF THE DRAWINGS

The present invention can be more fully understood by reading the subsequent detailed description and examples with references made to the accompanying drawings, wherein:

FIG. 1 is a schematic view of a method for forming a film on a surface of a substrate according to some embodiments of the present disclosure;

FIG. 2 is a schematic view of a timing sequence according to some embodiments of the present disclosure;

FIG. 3 is a schematic view of a method for forming a film on a surface of a substrate according to some embodiments of the present disclosure;

FIG. 4 is a schematic view of a semiconductor processing apparatus according to some embodiments of the present disclosure;

FIG. 5 is a schematic view of a semiconductor processing apparatus according to some embodiments of the present disclosure.

### DETAILED DESCRIPTION OF THE INVENTION

The present disclosure now will be described more fully hereinafter with reference to the accompanying drawings. The present disclosure may, however, be embodied in many different forms and should not be construed as limited to the embodiments set forth herein. Rather, these embodiments are provided so that this disclosure will be thorough and complete, and will fully convey the scope of the present disclosure to one of ordinary skill in the art.

It will be understood that although the terms “first,” “second,” and the like may be used herein to describe various members, regions, layers, and/or portions, these members, regions, layers, and/or portions should not be limited by these terms. The terms do not refer to a specific order, a vertical relationship, or a preference, and are only used to distinguish one member, region, or portion from another member, region, or portion. Accordingly, a first member, region, or portion that will be described below may refer to a second member, region, or portion without departing from the teaching of the present disclosure.

As used herein substantially or about the same means ±5%, ±2%, ±1%, or ±0.5% of another value or shape—e.g., one or more cross-sectional dimensions of the shape. The percentages can be absolute or relative.

In the drawings, variations from the shapes of the illustrations as a result, for example, of manufacturing techniques and/or tolerances, are to be expected. Thus, embodiments should not be construed as limited to the particular shapes of regions illustrated herein but may be to include deviations in shapes that result, for example, from manufacturing. Further, the drawing figures may be used to illustrate various features, which may not be drawn to scale.

Expressions, such as “at least one of,” when preceding a list of elements, modify the entire list of elements and do not modify the individual elements of the list.

As used herein, “atomic layer deposition”, abbreviated as “ALD”, refers to a method of depositing a film on a substrate by sequentially exposing its surface to alternate gas-phase reactants. In contrast to chemical vapor deposition, the different reactants are not simultaneously present in the reactor, but rather they are introduced as a series of sequential, non-overlapping pulses. In each of these pulses, the reactant reacts with the surface in a self-limiting way or a substantially self-limiting way. Further, ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “boron carbide” or “BₓC_{y}” refers to a material that comprises boron and carbon. In some embodiments, boron carbide may not include significant proportions of elements other than boron and carbon. In some embodiments, the boron carbide comprises B₄C. In some embodiments, the boron carbide may consist essentially of B₄C. In some embodiments, the boron carbide may not include stoichiometric boron carbide. In some cases, the boron carbide can include other elements, such as hydrogen.

As used herein, “boron carbonitride” or “BₓC_{y}N_{z}” refers to a material that that comprises boron, carbon, and nitrogen. Boron carbonitride may be represented by the formula BₓC_{y}N_{z} where the sum of x, y, and z is equal to 3. In some cases, the boron carbonitride may include other elements, such as hydrogen. The boron carbonitride may include boron carbide and boron nitride.

As used herein, “boron nitride” or “BₓN_{y}” refers to a material that that comprises boron and nitrogen. In some embodiments, boron nitride may not include significant proportions of elements other than boron and nitrogen. In some embodiments, the boron nitride comprises BN. In some embodiments, the boron nitride may consist essentially of BN. In some cases, the boron nitride may not include stoichiometric boron nitride. In some cases, the boron nitride can include other elements, such as hydrogen.

As used herein, “boron oxide” or “BₓO_{y}” refers to a material that that comprises boron and oxygen. In some embodiments, boron oxide may not include significant proportions of elements other than boron and oxygen. Boron oxide can be represented by the formula BₓO_{y}, where x can range from about 0 to about 6 and y can range from about 0 to about 3. In some embodiments, the boron oxide comprises B₂O₃. In some embodiments, the boron oxide may consist essentially of B₂O₃. In some cases, the boron oxide may not include stoichiometric boron oxide. In some cases, the boron oxide can include other elements, such as carbon and/or hydrogen.

As used herein, “chemical vapor deposition”, abbreviated as “CVD”, refers to a method of depositing a film on a substrate by exposing its surface to one or more gaseous reactants, which react and/or decompose on the substrate surface to produce a desired film. Typically, CVD is performed by co-introducing the reactants into a reactor.

As used herein, “chemisorption” refers to an adsorption process, caused by a reaction on an exposed surface, which creates, for example, a covalent or ionic bond between the surface and the adsorbate.

As used herein, a “film” refers to a continuous, substantially continuous, or non-continuous material that extends in a direction perpendicular to a thickness direction to cover at least a portion of a surface. A film can include two-dimensional materials, three-dimensional materials, nanoparticles or even partial or full molecular layers or partial or full atomic layers or clusters of atoms and/or molecules. A film may be built up from one or more non-discernable layers (e.g., monolayers or sub-monolayers) to produce a uniform or a substantially uniform material, wherein the number of layers influences the thickness of the material.

As used herein, a “gas” refers to a state of mater consisting of atoms or molecules that have neither a defined volume nor shape. A gas includes vaporized solid and/or liquid and may be constituted by a single gas or a mixture of gases, depending on the context.

As used herein, a “plasma” refers to an ionized gas comprising roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, they can provide very different fluxes of the various species.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

As used herein, “self-limiting” refers to a process that proceeds by a finite course and that terminates once the finite course is complete. For example, a self-limiting surface reaction terminates when the surface becomes saturated and all of the available and/or accessible surface reactive sites are depleted. At maximum one monolayer may be formed on the surface.

As used herein, “silicon carbide” or “SiC” refers to a material that includes silicon and carbon. In some embodiments, silicon carbide may not include significant proportions of elements other than silicon and carbon. Silicon carbide may be represented by the formula SiC. In some embodiments, the silicon carbide comprises SiC. In some embodiments, the silicon carbide may consist essentially of SiC. Silicon carbide need not necessarily be a stoichiometric composition. An amount of silicon can range from 5% to 50%; an amount of carbon can range from about 50% to about 95%. In some embodiments, SiC films may comprise one or more elements in addition to silicon and carbon, such as hydrogen and/or nitrogen.

As used herein, “silicon carbonitride” or “SiₓC_{y}N_{z}” or “SiCN” refers to a material that comprises silicon, carbon, and nitrogen. Silicon carbonitride may be represented by the formula SiₓC_{y}N_{z}. In some embodiments, the silicon carbonitride may comprise more Si—N bonds than Si—C bonds, for example, a ratio of Si—N bonds to Si—C bonds may be from about 1:10 to about 10:1. In some embodiments, the silicon carbonitride films may comprise from about 0% to about 50% carbon on an atomic basis. In some embodiments, the silicon carbonitride may comprise from about 0.1% to about 40%, from about 0.5% to about 30%, from about 1% to about 30%, or from about 5% to about 20% carbon on an atomic basis. In some embodiments, the silicon carbonitride may comprise from about 0% to about 70% nitrogen on an atomic basis. In some embodiments, the silicon carbonitride may comprise from about 10% to about 70%, from about 15% to about 50%, or from about 20% to about 40% nitrogen on an atomic basis. In some embodiments, the silicon carbonitride may comprise about 0% to about 50% silicon on an atomic basis. In some embodiments, the silicon carbonitride may comprise from about 10% to about 50%, from about 15% to about 40%, or from about 20% to about 35% silicon on an atomic basis. In some cases, the silicon carbonitride may include other elements, such as hydrogen. The silicon carbonitride may include silicon carbide and silicon nitride.

As used herein, “silicon nitride” or “SiₓN_{y}” refers to a material that includes silicon and nitrogen. In some embodiments, silicon nitride may not include significant proportions of elements other than silicon and nitrogen. Silicon nitride may be represented by the formula Si₃N₄. In some embodiments, the silicon nitride comprises Si₃N₄. In some embodiments, the silicon nitride may consist essentially of Si₃N₄. In some cases, the silicon nitride may not include stoichiometric silicon nitride. In some cases, the silicon nitride may include other elements, such as carbon, oxygen, and/or hydrogen.

As used herein, “silicon oxide” or “SiOₓ” refers to a material that includes silicon and oxygen. Silicon oxide can be represented by the formula SiOₓ, where x can be between 0 and 2. In some embodiments, silicon oxide may not include significant proportions of elements other than silicon and oxygen. Silicon oxide may be represented by the formula SiO₂. In some embodiments, the silicon oxide comprises SiO₂. In some embodiments, the silicon oxide may consist essentially of SiO₂. In some cases, the silicon oxide may not include stoichiometric silicon oxide. In some cases, the silicon oxide can include other elements, such as carbon, nitrogen, and/or hydrogen.

As used herein, “silicon oxycarbide” or “Si_{z}OₓC_{y}” or “SiOC” refers to material that comprises silicon, oxygen, and carbon. As used herein, unless stated otherwise, SiOC is not intended to limit, restrict, or define the bonding or chemical state, for example, the oxidation state of any of Si, O, C, and/or any other element in the film. In some embodiments, the Si_{z}OₓC_{y} may comprise Si—C bonds and/or Si—O bonds. In some embodiments, the SiOC may comprise Si—C bonds and Si—O bonds and may not comprise Si—N bonds. In some embodiments, the SiOC may comprise Si—H bonds in addition to Si—C and/or Si—O bonds. In some embodiments, the SiOC may comprise more Si—O bonds than Si—C bonds, for example, a ratio of Si—O bonds to Si—C bonds may be from about 1:10 to about 10:1. In some embodiments, the SiOC may comprise from about 0% to about 50% carbon on an atomic basis. In some embodiments, the SiOC may comprise from about 0.1% to about 40%, from about 0.5% to about 30%, from about 1% to about 30%, or from about 5% to about 20% carbon on an atomic basis. In some embodiments, the SiOC may comprise from about 0% to about 70% oxygen on an atomic basis. In some embodiments, the SiOC may comprise from about 10% to about 70%, from about 15% to about 50%, or from about 20% to about 40% oxygen on an atomic basis. In some embodiments, the SiOC may comprise about 0% to about 50% silicon on an atomic basis. In some embodiments, the SiOC films may comprise from about 10% to about 50%, from about 15% to about 40%, or from about 20% to about 35% silicon on an atomic basis. In some embodiments, silicon oxycarbide can be represented by the chemical formula Si_{z}OₓC_{y}, where z can range from about 0 to about 2, x can range from about 0 to about 2, and y can range from about 0 to about 5.

As used herein, “silicon oxycarbonitride” or “Si_{z}OₓC_{y}N_{w}” or “SiOCN” refers to material that comprises silicon, oxygen, nitrogen, and carbon. As used herein, unless stated otherwise, SiOCN is not intended to limit, restrict, or define the bonding or chemical state, for example, the oxidation state of any of Si, 0, C, N and/or any other element in the material. In some embodiments, SiOCN is material that can be represented by the chemical formula Si_{z}OₓC_{y}N_{w}, where z can range from about 0 to about 2, x can range from about 0 to about 2, y can range from about 0 to about 2, and w can range from about 0 to about 2.

As used herein, “silicon oxynitride” or “SiOₓN_{y}” refers to a material that includes silicon, oxygen, and nitrogen. As used herein, unless stated otherwise, SiOₓN_{y} is not intended to limit, restrict, or define the bonding or chemical state, for example, the oxidation state of any of Si, O, N and/or any other element in the material. In some embodiments, SiOₓN_{y} is material that can be represented by the chemical formula SiOₓN_{y}, where x can range from about 0 to about 2, y can range from about 0 to about 2. The silicon oxynitride may include silicon oxide and silicon nitride.

As used herein, a “substrate” refers to an underlying material or materials that may be used to form, or upon which, a device, a circuit, material, or material layer may be formed. The substrate may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide. A substrate can include one or more layers overlying a bulk material, for example the substrate may include nitrides, for example TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. The substrate can include various topologies, such as gaps, including recesses, lines, trenches, or spaces between elevated portions, such as fins, and the like formed within or on at least a portion of a layer of the substrate.

As used herein, an “ion trap” refers to a structure, region, device, or configuration within a semiconductor processing chamber, such as a plasma-enhanced atomic layer deposition (PE-ALD) or radical-enhanced atomic layer deposition (RE-ALD) chamber, that is designed to selectively capture, retain, and control ionic species generated during deposition processes. The ion trap may be integrated into or positioned adjacent to the interior surfaces of the chamber, including, for example, chamber walls, gas distribution plates, or other internal components, to manage the energy, directionality, and concentration of ions within the reaction space. By influencing ion trajectories and reducing undesirable ion bombardment or plasma-induced damage to substrates and underlying device structures, the ion trap can help maintain optimal conditions for uniform and conformal film growth. The ion trap may be formed from various conductive, semiconductive, or dielectric materials, and can include engineered geometries, patterned surfaces, coatings, or other configurations tailored to the specific process chemistries, power levels, and plasma conditions of interest. In certain embodiments, the ion trap may be dynamically adjusted or tuned to accommodate changing process parameters, thereby improving process stability, film quality, and overall device performance in advanced semiconductor fabrication environments.

As used herein, a “substituent” refers to an atom or a group of atoms that replaces one or more atoms (such as a hydrogen atom) or groups of atoms in a parent compound, thereby resulting in a new compound. The substituent is substituted for the original atom or a group of atoms in the parent molecule. For simplicity, a substituent may be indicated in a chemical formula as an “R” group and each “R” group in a compound may be independently selected unless otherwise specifically indicated that this is not the case. Examples of substituent groups include, but are not limited to: a hydrogen atom (H); an “alkyl group”, such as a saturated linear or branched C₁ to C₁₀ hydrocarbons, preferably C₁ to C₆ hydrocarbons (e.g., methyl, ethyl, propyl, iso-propyl, butyl, i-butyl, s-butyl, t-butyl, pentyl, 3-pentyl, neo-pentyl, and hexyl); a “cycloalkyl group”, such as C₃ to C₆ cyclic hydrocarbons (e.g., cyclopropyl, cyclobutyl, cyclopentyl, and cyclohexyl); an “alkenyl group”, such as C₂ to C₆ linear or branched unsaturated hydrocarbons (e.g., vinyl, allyl, propenyl, butenyl, pentenyl, hexenyl, butadienyl, pentadienyl, hexadienyl, ethynyl, propargyl, butynyl, pentynyl, and hexynyl); an “aryl group”, such as a phenyl, benzyl, tolyl, xylyl, naphthyl, cyclopentadienyl, and methyl, dimethyl, or ethyl cyclopentadienyl groups; a hydroxy group (OH); an “alkoxy group”, such as a linear or branched C₁ to C₁₀ alkoxy group, typically a C₁ to C₄ alkoxy group (e.g., methoxy, ethoxy, n-propoxy, i-propoxy, butoxy, iso-butoxy, sec-butoxy, and tert-butoxy); a hydroxyalkyl group such as a linear or branched a C₁ to C₁₀ hydroxyalkyl, typically a linear or branched C₁ to C₄ hydroxyalkyl (e.g., hydroxymethyl, hydroxyethyl, hydroxypropyl, hydroxybutyl, hydroxypentyl, and hydroxyhexyl); an “alkoxycarbonyl group”, such as a linear or branched C₁ to C₆ carbonyl hydrocarbon (e.g., methoxycarbonyl, ethoxycarbonyl, propoxycarbonyl, isopropoxycarbonyl, butoxycarbonyl, pentoxycarbonyl, and hexyloxycarbonyl); a thiol group (SH); an “alkylthiol group”, such as a linear or branched C₁ to C₆ thiols (e.g., thiolmethyl, thiolethyl, thiolpropyl, thiolbutyl, thiolpentyl, and thiolhexyl); a halide (X), such as fluoride (F), chloride (Cl), bromide (Br), and iodide (I); and an “haloalkyl group”, such as a linear or branched C₁ to C₆ alkylhalides having one or more halogen atoms (e.g., iodomethyl, bromomethyl, chloromethyl, fluoromethyl, trifluoromethyl, 2-chloroethyl, 2-fluoroethyl, 2,2,2-trifluoroethyl, and pentafluoroethyl). A substituent group may, in and of itself, be substituted. For example, a hydroxyalkyl group is a substituted alkyl group, where a H atom on the alkyl group is replaced with an OH group.

As used herein, “radicalizing” refers to a process that involves converting stable precursor or reactant gases into radicals—highly reactive neutral species with unpaired electrons—in a semiconductor deposition chamber environment, such as during plasma-enhanced atomic layer deposition (PE-ALD) or radical-enhanced atomic layer deposition (RE-ALD). These radicals may be generated by introducing energy sources (e.g., plasma, photons, thermal energy) that dissociate gas-phase molecules into more reactive fragments. The radicalizing process can occur within, or in proximity to, the deposition chamber and may be achieved through dedicated radical-generating zones, plasma sources, radical injectors, or other field-generating components. By producing a controlled population of radicals, the radicalizing process enhances reaction kinetics, improves the overall chemical reactivity at the substrate surface, and enables more uniform, conformal, and efficient film deposition. These radicals may react with various substrate surfaces, including silicon-based materials, metals, nitrides, oxides, and other semiconductor or dielectric materials, facilitating tailored surface modification or layer formation. The radicalizing process may be dynamically adjusted by controlling parameters such as gas flow, chamber pressure, plasma power, or residence time of the precursor species, thereby allowing for fine-tuning of the film properties, improved process stability, and enhanced device performance in advanced semiconductor fabrication environments.

Articles “a” or “an” refer to a species or a genus including multiple species, depending on the context. As such, the terms “a/an”, “one or more” and “at least one” can be used interchangeably herein. It is also to be noted that the terms “comprising”, “including”, and “having” can be used interchangeably.

The term “about” generally refers to a range of numbers that is considered equivalent to the recited value (e.g., having the same function or result). In some instances, the term about may include numbers that are rounded to the nearest significant figure.

The term “essentially” as applied to a composition, a method, or a system generally means that the additional components do not substantially modify the properties and/or function of the composition, the method, or the system.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

The present disclosure generally relates to methods of forming a film on the surface of a substrate using plasma enhanced atomic-layer deposition (PE-ALD) and systems for performing such methods, and in particular to the use of a low-power plasma to affect partial breakdown of chemical precursors to enhance their reactivity. More specifically, the present disclosure generally relates to methods of forming a film on the surface of a substrate using radical-enhanced atomic-layer deposition (RE-ALD) and systems for performing such methods, and in particular to the use of a low-power plasma to affect partial breakdown of chemical precursors to enhance their reactivity. Various aspects of the methods and systems and the benefits derived therefrom will now be described.

Finding improved chemical precursors for ALD processes is an ongoing effort, as increasingly stringent material and process requirements need to be met in order to enable improvement of semiconductor devices. In general, precursors are sought that are readily volatilizable and transportable to the deposition location, at temperatures consistent with fabrication of device structures. Desirable precursors may produce highly conformal films on the substrate with which the precursor vapor is contacted, without the occurrence of decomposition reactions that would adversely impact the product device structure. A typical way to work with relatively unreactive chemicals is to utilize plasma processing, but this has its own disadvantages (e.g., plasma induced damage, anisotropy) and the options are limited if the precursor is too unreactive to even chemisorb on the substrate surface. In this regard, disclosed herein are methods and systems for depositing a film on a surface of a substrate using a low-power plasma to partially breakdown precursors to increase their reactivity. The methods and systems disclosed herein advantageously expand the selection of precursors and allow for the use of relatively “non-reactive” precursors that may not readily chemisorb on a substrate surface and/or participate in thermal ALD reactions. The disclosed methods can improve film growth rates, allow for lower-temperature processing, and improve the uniformity and conformality of the film, while minimizing the negative effects typically associated with plasma-processing. These and other advantages will be apparent from the disclosure of the various aspects, embodiments, and configurations contained herein.

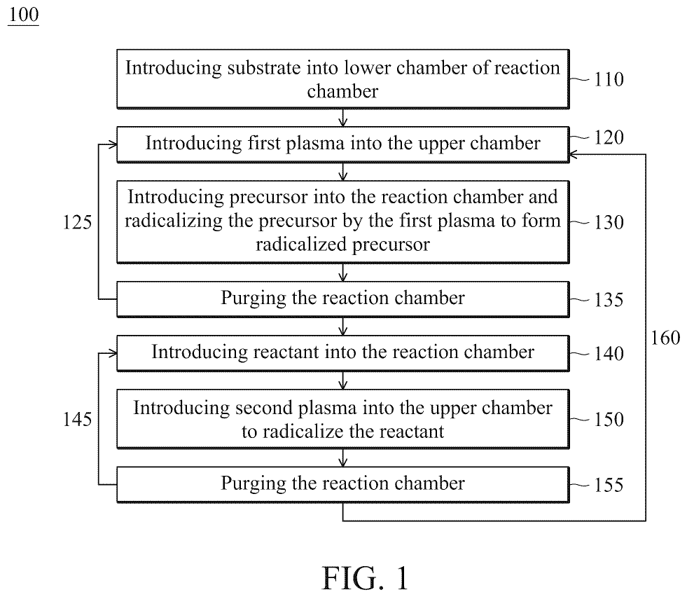

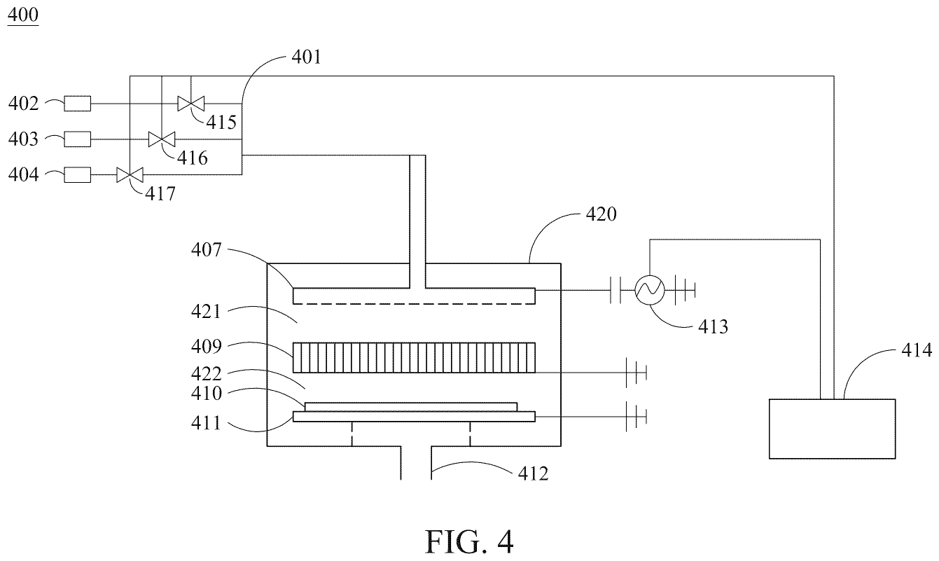

Please refer to FIG. 1, FIG. 1 is a schematic view of a method 100 for forming a film on the surface of a substrate according to some embodiments of the present disclosure. In step 110, introducing a substrate into the lower chamber of a reaction chamber. The reaction chamber is separated into an upper chamber and a lower chamber using an ion trap. The ion trap can be a mesh plate that is made of metal (such as aluminum), and the ion trap is grounded. The details of the ion trap can be seen in FIG. 4 and related paragraphs. Next, step 120 involves introducing a first plasma into the upper chamber. The first plasma is introduced into the upper chamber by a top plate disposed within the reaction chamber. The plasma is a low-power plasma, and the first plasma is constrained by the upper chamber (i.e., between the top plate and the ion trap).

According to some embodiments of the present disclosure, the top plate is a showerhead that provides gases (such as a carrier gas, a precursor, a reactant, or a combination thereof) into the reaction chamber. The showerhead is connected to an RF generator to form the first plasma in the upper chamber. The RF power for generating the first plasma can be varied in different embodiments of the current disclosure. As will be appreciated, the power for generating the first plasma, and hence the ionization energy of the plasma, may vary based on the type of precursor and may be tuned to affect the degree of dissociation of the precursor and the chemisorption onto the substrate surface. The RF power should be set high enough to form activated radical species based on the precursor but low enough such that the breakdown is insufficient to cause CVD-type film deposition. Typically, the RF power for generating the first plasma is maintained at about 100 W or less, typically at about 50 W or less, typically at about 25 W or less, or more typically at about 20 W. Typically, the RF power for generating the first plasma is maintained at about 0.1 W or higher, typically at about 1 W or higher, typically at about 5 W or higher, or more typically at about 20 W. (In comparison, the RF power for traditional PE-ALD processes is much higher, typically between 100-1,500 W). At such low RF powers, the first plasma may be characterized as having a low degree of ionization and a low electron density.

In some embodiments, the RF power for generating the first plasma is maintained at about 100 W or less, typically from about 0.1 W to about 100 W, more typically from about 1 W to about 100 W, more typically from about 1 W to about 90 W, more typically from about 1 W to about 80 W, more typically from about 1 W to about 70 W, more typically from about 1 W to about 60 W, more typically from about 1 W to about 50 W, more typically from about 1 W to about 40 W, more typically from about 1 W to about 30 W, more typically from about 1 W to about 20 W, more typically from about 1 W to about 10 W, more typically from about 5 W to about 100 W, more typically from about 5 W to about 90 W, more typically from about 5 W to about 80 W, more typically from about 5 W to about 70 W, more typically from about 5 W to about 60 W, more typically from about 5 W to about 50 W, more typically from about 5 W to about 40 W, more typically from about 5 W to about 30 W, more typically from about 5 W to about 20 W, more typically from about 10 W to about 100 W, more typically from about 10 W to about 90 W, more typically from about 10 W to about 80 W, more typically from about 10 W to about 70 W, more typically from about 10 W to about 60 W, more typically from about 10 W to about 50 W, more typically from about 10 W to about 40 W, more typically from about 10 W to about 30 W, or any intermediate range of powers between about 0.1 W and about 100 W. In some embodiments, the RF power may be maintained at about 100 W or less, at about 90 W or less, at about 80 W or less, at about 70 W or less, at about 60 W or less, at about 50 W or less, at about 40 W or less, at about 30 W or less, at about 25 W or less, at about 20 W or less, at about 15 W or less, or at about 10 W or less. In some embodiments, the RF power may be maintained at about 1 W, at about 5 W, at about 10 W, at about 20 W, at about 25 W, at about 30 W, at about 40 W, at about 50 W, at about 60 W, at about 70 W, at about 80 W, at about 90 W, or at about 100 W.

In some embodiments, the duration of the first plasma is about 100 seconds or less, typically from about 0.01 seconds to about 100 seconds, more typically from about 0.01 seconds to about 50 seconds, more typically from about 0.01 seconds to about 10 seconds, more typically from about 0.01 s second to about 5 seconds, more typically from about 0.01 seconds to about 1 second, more typically from about 0.01 seconds to about 0.5 seconds, more typically from about 0.01 seconds to about 0.1 seconds, more typically from about 0.1 seconds to about 100 seconds, more typically from about 1 second to about 50 seconds, more typically from about 0.1 seconds to about 10 seconds, more typically from about 0.1 seconds to about 5 seconds, more typically from about 0.1 seconds to about 1 second, more typically from about 0.1 seconds to about 0.5 seconds, more typically from about 0.5 seconds to about 100 seconds, more typically from about 0.5 seconds to about 50 seconds, more typically from about 0.5 seconds to about 10 seconds, more typically from about 0.5 seconds to about 5 seconds, more typically from about 0.5 seconds to about 1 second, more typically from about 1 second to about 100 seconds, more typically from about 1 second to about 50 seconds, more typically from about 1 second to about 10 seconds, more typically from about 1 second to about 5 seconds, more typically from about 5 seconds to about 100 seconds, more typically from about 5 seconds to about 50 seconds, more typically from about 5 seconds to about 10 seconds, or any intermediate range of times between about 0.01 seconds and about 100 seconds. In some embodiments, the RF power may be maintained at about 100 seconds or less, about 50 seconds or less, about 10 seconds or less, about 5 seconds or less, about 1 second or less, about 0.5 seconds or less, about 0.1 seconds or less. In some embodiments, the RF power may be maintained at about 0.01 seconds, about 0.1 seconds, about 0.5 seconds, about 1 second, about 5 seconds, about 10 seconds, about 50 seconds, or about 100 seconds.

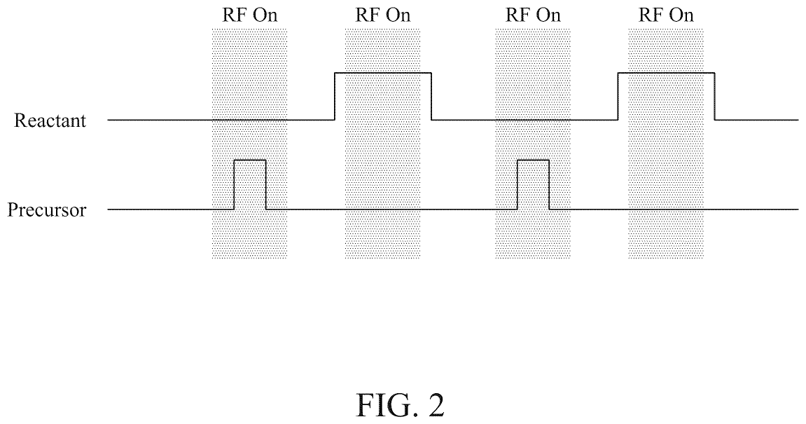

Next, in step 130, a precursor is introduced into the reaction chamber and the precursor is radicalized by the first plasma to form a radicalized precursor. The precursor is brought into the reaction chamber through the showerhead by a carrier gas. The precursor is dosed or pulsed into the continuous flow of the carrier gas. In some embodiments, the carrier gas may be the feed gas for the plasma discharge. In some embodiments, the precursor comprises a silazane (such as hexamethyldisilazane ([(CH₃)₃Si]₂NH), hexamethylcyclotrisilazane (C₆H₂₁N₃Si₃), perhydropolysilazane ([SiH₂NH]ₙ)). In some embodiments, the first plasma is generated from a gas that is substantially containing only a noble gas. In some embodiments, the first plasma is generated from a noble gas. The noble gas may be selected from a group consisting of helium (He), neon (Ne), argon (Ar), krypton (Kr), xenon (Xe), and mixtures thereof. The carrier gas may help to excite and partially breakdown the precursor when RF power is applied, but it does not chemically react with the precursor. In other embodiments, one or more additives may be introduced either with the precursor or separately from the precursor. The low-power plasma is ignited by pulsing the RF power. The duration of the RF power pulse should at least partially overlap with the duration of the precursor pulse. The relative timing of the low-power plasma and precursor pulses may be used to tune the degree of precursor breakdown and radicalization. In some embodiments, the RF power and the precursor pulse are initiated simultaneously. In some embodiments, the RF power is initiated later than the precursor pulse. In some embodiments, the precursor pulse is initiated later than the RF power. In some embodiments, the precursor is pulsed after the RF power is pulsed such that the duration of the two pulses overlaps (e.g., see FIG. 2). In other embodiments, the duration of the RF power pulse is longer than the duration of the precursor pulse. Since the chemisorption step is a self-limiting or substantially self-limiting process, the number of deposited precursor molecules is determined by or predominantly determined by the number of accessible reactive sites on the surface and is independent of the exposure time after saturation of the surface. Excess precursor may be supplied into the reaction chamber, and the duration of the precursor and plasma pulses should be long enough for the surface to become saturated. Typical plasma/precursor pulse times range from about 0.1 second up to about 10 seconds, preferably from about 1 second to about 5 seconds, after which the reaction chamber may be flushed or purged to remove unreacted precursor, gaseous reaction by-products, and other species.

Next, step 140 involves introducing a reactant (such as a reactive gas) into the reaction chamber. In some embodiments, the reactive gas is entrained in or pulsed into the continuous flow of the carrier gas into the reaction chamber. In some embodiments, the reactive gas is a precursor (and may be referred to as the second precursor) meaning that a portion of the reactive gas (an element or group within the reactive gas) is incorporated into resultant film. For example, the reactive species may react with the chemisorbed layer via an exchange reaction or an addition reaction. In other embodiment, the reactive gas may chemically modify the chemisorbed layer, for example, by an elimination reaction or by oxidation or reduction to form a film, but no element or groups within the reactive species is incorporated into the resultant film. The choice of the reactive gas will depend upon the composition of the chemisorbed layer and the desired film. In some embodiments, the deposition reaction may proceed via a thermal process, whereby the reactive gas thermally reacts with the chemisorbed layer on the substrate surface. In other embodiments, the deposition reaction may proceed via a plasma-enhanced process, whereby the reactive gas comprises excited species and/or radicals which react with the chemisorbed layer. As with the adsorption step, the deposition step is also a self-limiting or substantially self-limiting process, determined by the number of deposited precursor molecules on the surface and is independent of the exposure time after saturation. Excess reactive gas may be provided, and the duration of the reactive gas pulse should be long enough for the chemisorbed layer to substantially or completely transform into the target layer. Typical exposure or pulse times range from about 0.1 seconds up to about 10 seconds, preferably from about 1 second to about 5 seconds, after which the reaction chamber is flushed or purged to remove any unreacted reactive gas, gaseous reaction by-products, and other species.

Next, step 150 involves introducing a second plasma into the upper chamber to radicalize the reactant. The showerhead is connected to the RF generator to form the second plasma in the upper chamber. The second plasma may be formed using a feed gas comprising a carrier gas (inert gas), a reactive gas, or a mixture of gases. The feed gas is fed into the reaction chamber and the second plasma is pulsed. In some embodiments, the second plasma is generated from a feed gas comprising a reactive gas which may optionally be mixed or co-fed with a carrier gas. In other embodiments, the second plasma is generated from a reactive gas. The reactive gas may be, by way of non-limiting example, oxygen (O₂), nitrogen (N₂), ammonia (NH₃), hydrogen (H₂), and mixtures thereof. The carrier gas may be a noble gas selected from the group consisting of helium (He), neon (Ne), argon (Ar), krypton (Kr), xenon (Xe), and mixtures thereof. The excited species from noble gases in the second plasma do not necessarily contribute material to the deposited film but can, in some circumstances, contribute to film growth as well as help in the formation and ignition of the second plasma. In some embodiments, the feed gas comprises oxygen. In some embodiments, the feed gas comprises nitrogen. In some embodiments, the feed gas comprises ammonia. In some embodiments, the feed gas comprises hydrogen. In some embodiments, the feed gas comprises nitrogen and hydrogen. In some embodiments, the feed gas comprises an oxygen containing compound that forms O* atoms in the second plasma. In some embodiments, the feed gas comprises a nitrogen containing compound that forms N* atoms in the second plasma. In some embodiments, the feed gas comprises a hydrogen containing compound that forms H* atoms in the second plasma.

In some embodiments, the RF power for generating the second plasma is maintained at about 500 W or less, typically from about 5 W to about 500 W, more typically from about 5 W to about 400 W, more typically from about 5 W to about 300 W, more typically from about 5 W to about 250 W, more typically from about 5 W to about 200 W, more typically from about 5 W to about 150 W, more typically from about 5 W to about 100 W, more typically from about 5 W to about 50 W, more typically from about 5 W to about 10 W, more typically from about 10 W to about 500 W, more typically from about 10 W to about 400 W, more typically from about 10 W to about 300 W, more typically from about 10 W to about 250 W, more typically from about 10 W to about 200 W, more typically from about 10 W to about 150 W, more typically from about 10 W to about 100 W, more typically from about 10 W to about 50 W, more typically from about 50 W to about 500 W, more typically from about 50 W to about 400 W, more typically from about 50 W to about 300 W, more typically from about 50 W to about 250 W, more typically from about 50 W to about 200 W, more typically from about 50 W to about 150 W, more typically from about 50 W to about 100 W, more typically from about 100 W to about 500 W, more typically from about 100 W to about 400 W, more typically from about 100 W to about 300 W, more typically from about 100 W to about 250 W, more typically from about 100 W to about 200 W, more typically from about 100 W to about 150 W, more typically from about 150 W to about 500 W, more typically from about 150 W to about 400 W, more typically from about 150 W to about 300 W, more typically from about 150 W to about 250 W, more typically from about 150 W to about 200 W, or any intermediate range of powers between about 5 W and about 500 W. In some embodiments, the RF power may be maintained at about 500 W or less, at about 400 W or less, at about 300 W or less, at about 250 W or less, at about 200 W or less, at about 150 W or less, at about 100 W or less, at about 50 W or less, at about 10 W. In some embodiments, the RF power may be maintained, at about 5 W, at about 10 W, at about 50 W, at about 100 W, at about 150 W, at about 200 W, at about 250 W, at about 300 W, at about 400 W, or at about 500 W. In some embodiments, the RF power of the second plasma is higher than the RF power of the first plasma.

In some embodiments, the duration of the second plasma can be similar to the duration of the first plasma, which is described above. In some embodiments, the duration of the second plasma is the same as the duration of the first plasma. In some embodiments, the duration of the second plasma is longer than the duration of the first plasma. In some embodiments, the duration of the second plasma is shorter than the duration of the first plasma.

In some embodiments, the method 100 further includes step 135 and step 155. Step 135 is performed between step 130 and step 140, while step 155 is performed after step 150. In step 135 and step 155, the reaction chamber is purged to remove unreacted chemicals (e.g., precursors and reactive gases) and gas-phase reaction by-products from the surface of the substrate. Purging may be effected, for example, by evacuating the reaction chamber with a vacuum pump and/or by replacing the gas inside a reaction chamber with an inert or substantially inert gas such as argon or nitrogen. In some instances, a purging step may be implemented between two pulses of gases which react with each other or, in other instances, purging may be implemented between two pulses of gases that do not react with each other. Purging may avoid, or at least reduce, gas-phase interactions between two gases reacting with each other. It shall be understood that a purge can be affected either in time or in space, or both. For example, in the case of temporal purges, a purge step can be used in the temporal sequence of introducing a precursor into a reaction chamber, introducing a purge gas into the reaction chamber, and then introducing a reactive gas into the reaction chamber, wherein the substrate on which the material is deposited does not move.

In some embodiments, step 120, step 130 and step 135 form a sub-cycle 125. Sub-cycle 125 can be repeated until the substrate is substantially or completely formed with a chemisorbed layer. In some embodiments, step 140, step 150 and step 155 form a sub-cycle 145. Sub-cycle 145 can be repeated until the chemisorbed layer on the substrate is substantially or completely transformed into the target layer. In some embodiments, step 120, step 130, step 135, step 140, step 150 and step 155 form a cycle 160. Cycle 160 can be repeated until a film with desired thickness is formed on the substrate.

In some embodiments, cycle 160 is repeated at least 1 time or more, typically from 1 time to about 10,000 times, more typically from 1 time to about 1,000 times, more typically from 1 time to about 100 times, more typically from 1 time to about 10 times, more typically from 10 times to about 10,000 times, more typically from 10 times to about 1,000 times, more typically from 10 times to about 100 times, more typically from 100 times to about 10,000 times, more typically from 100 times to about 1,000 times, more typically from 1,000 times to about 10,000 times. In some embodiments, cycle 160 is repeated at least 1 time, about 10 times, about 100 times, about 1,000 times, or about 10,000 times.

Please refer to FIG. 2, FIG. 2 is a schematic view of a timing sequence according to some embodiments of the present disclosure. The first plasma is ignited before the precursor is introduced into the reaction chamber, and the first plasma pulse continues after the precursor pulse ends. The second plasma is ignited after the reactant is introduced into the reaction chamber, and the second plasma pulse ends before the reactant pulse ends. FIG. 2 show that the cycle 160 is repeated for 1 time. In some embodiments, the first plasma is ignited while the precursor is introduced into the reaction chamber. In some embodiments, the first plasma is ignited after the precursor is introduced into the reaction chamber. In some embodiments, the first plasma pulse ends while the reactant pulse ends. In some embodiments, the first plasma pulse ends before the reactant pulse ends. In some embodiments, second plasma is ignited while the reactant is introduced into the reaction chamber. In some embodiments, second plasma is ignited before the reactant is introduced into the reaction chamber. In some embodiments, the second plasma pulse ends while the reactant pulse ends. In some embodiments, the second plasma pulse ends after the reactant pulse ends. In some embodiments, cycle 160 is repeated until a film with desired thickness is formed.

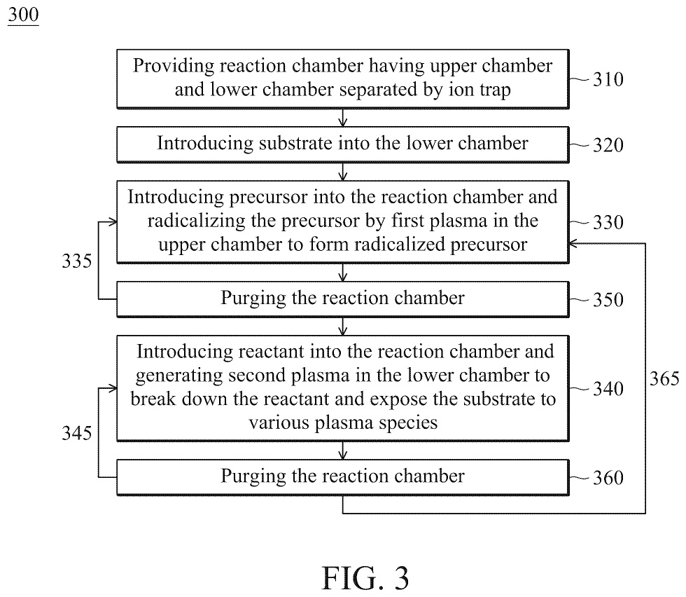

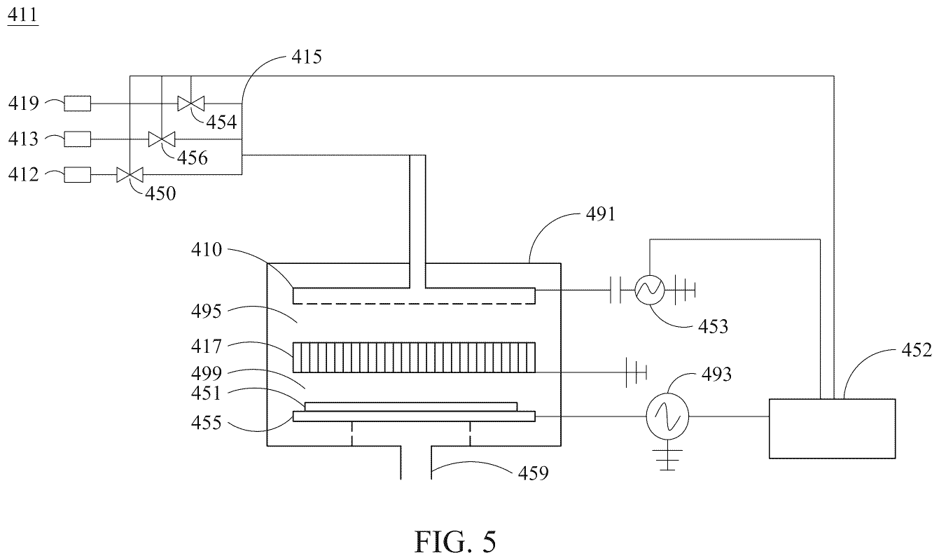

Please refer to FIG. 3, FIG. 3 is a schematic view of a method 300 for forming a film on the surface of a substrate according to some embodiments of the present disclosure. In step 310, providing a reaction chamber having an upper chamber and a lower chamber separated by an ion trap. The upper chamber is between the top plate and the ion trap, while the lower chamber is between the ion trap and the susceptor. The ion trap can be a mesh plate that is made of metal (such as aluminum), and the ion trap is grounded. The details of the ion trap can be seen in FIG. 5 and related paragraphs. Next, step 320 involves introducing a substrate into the lower chamber. The substrate is disposed on the susceptor and is between the ion trap and susceptor. Next, step 330 involves introducing a precursor into the reaction chamber and radicalizing the precursor using a first plasma in the upper chamber to form a radicalized precursor. According to some embodiments of the present disclosure, the top plate is a showerhead that provides gases (such as carrier gas, precursor, and/or reactant) into the reaction chamber. The showerhead is connected to a first RF generator to form the first plasma in the upper chamber. The precursor and the first plasma in method 300 is similar to the precursor and the first plasma in method 100, and so the description is not repeated herein.

Next, step 340 involves introducing a reactant (reactive gas) into the reaction chamber and generating a second plasma in the lower chamber to break down the reactant and expose the substrate to various plasma species. The reactant in method 300 is similar to the reactant in method 100, and so the description is not repeated herein. The susceptor is connected to a second RF generator to form the second plasma in the lower chamber. The reactant comprises one or more excited and/or radical species that may be formed in situ in the reaction chamber using a direct plasma formed near the vicinity or directly above the substrate. Generally, use of a direct plasma results in a higher density of plasma species (e.g., ions, electrons, radicals, and other excited species) near the substrate and those species may interact with the substrate and influence the film growth and quality.

The second plasma may be formed using a feed gas comprising a carrier gas (inert gas), a reactive gas, or a mixture of gasses. The feed gas is fed into the reaction chamber and the plasma is pulsed. In some embodiments, the plasma is generated from a feed gas comprising a reactive gas which may optionally be mixed or co-fed with a carrier gas. In other embodiments, the plasma is generated from a reactive gas. The reactive gas may be, by way of non-limiting example, oxygen (O₂), nitrogen (N₂), ammonia (NH₃), hydrogen (H₂), and mixtures thereof. The carrier gas may be a noble gas selected from the group consisting of helium (He), neon (Ne), argon (Ar), krypton (Kr), xenon (Xe), and mixtures thereof. The excited species from noble gases in the plasma do not necessarily contribute material to the deposited film but can, in some circumstances, contribute to film growth as well as help in the formation and ignition of the plasma. In some embodiments, the feed gas comprises oxygen. In some embodiments, the feed gas comprises nitrogen. In some embodiments, the feed gas comprises ammonia. In some embodiments, the feed gas comprises hydrogen. In some embodiments, the feed gas comprises nitrogen and hydrogen. In some embodiments, the feed gas comprises an oxygen containing compound that forms O* atoms in the plasma. In some embodiments, the feed gas comprises a nitrogen containing compound that forms N* atoms in the plasma. In some embodiments, the feed gas comprises a hydrogen containing compound that forms H* atoms in the plasma.

The RF power for generating the second plasma can be varied in different embodiments of the current disclosure. In some embodiments, the power for generating the second plasma is typically from about 10 W to about 1,500 W, more typically from about 20 W to about 1,000 W, more typically from about 20 W to about 900 W, more typically from about 20 W to about 800 W, more typically from about 20 W to about 700 W, more typically from about 20 W to about 600 W, more typically from about 20 W to about 500 W, more typically from about 20 W to about 400 W, more typically from about 20 W to about 300 W, more typically from about 20 W to about 200 W, more typically from about 20 W to about 100 W, or any intermediate range of powers between about 10 W and about 1,500 W. In some embodiments, the RF power for generating the second plasma may be maintained at about 20 W, at about 30 W, at about 40 W, at about 50 W, at about 60 W, at about 70 W, at about 80 W, at about 90 W, at about 100 W, at about 120 W, at about 140 W, at about 160 W, at about 180 W, at about 200 W, at about 220 W, at about 240 W, at about 260 W, at about 280 W, at about 300 W, at about 320 W, at about 340 W, at about 360 W, at about 380 W, at about 400 W, at about 420 W, at about 440 W, at about 460 W, at about 480 W, at about 500 W, at about 520 W, at about 540 W, at about 560 W, at about 580 W, at about 600 W, at about 620 W, at about 640 W, at about 660 W, at about 680 W, at about 700 W, at about 720 W, at about 740 W, at about 760 W, at about 780 W, at about 800 W, at about 820 W, at about 840 W, at about 860 W, at about 880 W, at about 900 W, at about 920 W, at about 940 W, at about 960 W, at about 980 W, or at about 1,000 W. Adjusting the power of the plasma generator can affect the amount/density and energy of reactive species generated by plasma. Without limiting the disclosed method to any specific theory, higher power may lead to the generation of higher energy ions and radicals. This may affect the degree of damage that the reactive species may cause on the surfaces of the substrate.

In method 300, the duration of the second plasma can be similar to the duration of the first plasma, which is described above. In some embodiments, the duration of the second plasma is the same as the duration of the first plasma. In some embodiments, the duration of the second plasma is longer than the duration of the first plasma. In some embodiments, the duration of the second plasma is shorter than the duration of the first plasma.

In some embodiments, the method 300 further includes step 350 and step 360. Step 350 is performed between step 330 and step 340, while step 360 is performed after step 340. Step 350 and step 360 are similar to step 135 and step 155, respectively, and so the description is not repeated herein.

In some embodiments, step 330 and step 350 form a sub-cycle 335. Sub-cycle 335 can be repeated until the substrate is substantially or completely formed with a chemisorbed layer. In some embodiments, step 340 and step 360 form a sub-cycle 345. Sub-cycle 345 can be repeated until the chemisorbed layer on the substrate is substantially or completely transformed into the target layer. In some embodiments, step 330, step 350, step 140 and step 360 form a cycle 365. Cycle 365 can be repeated until a film with desired thickness is formed on the substrate.

The timing sequence of method 300 is similar to the timing sequence (FIG. 2) of method 100, and so the description is not repeated herein.

Please refer to FIG. 4, FIG. 4 is a schematic view of a semiconductor processing apparatus 400 according to some embodiments of the present disclosure. The semiconductor processing apparatus 400 is an implementation of method 100. Therefore, the element and/or component describe herein can be connected to method 100.

A carrier gas is supplied from a carrier gas source 402 through a gas manifold 401 into the reaction chamber 420. The carrier gas flows through a showerhead 407 that is positioned directly above a susceptor 411 on which a substrate (i.e., a wafer) 410 is placed. A precursor is also supplied from a precursor source 403, in the form of a gas, through the gas manifold 401 into the reaction chamber 420 through the showerhead 407. The precursor may be vaporized and entrained in or pulsed into the carrier gas. A reactant is supplied from a reactant source 404, in the form of a gas, through the gas manifold 401 into the reaction chamber 420 through the showerhead 407. The semiconductor processing apparatus 400 is also configured to allow for the introduction of other gases, such as other reactant (reactive gas) and other gases (e.g., other carrier gases, precursors or reactive gases, carrier, dilutant, process, feed, and/or purging gases), either through the showerhead 407 or from other ports (not shown) into the reaction chamber 420. Thus, the semiconductor processing apparatus 400 may include other sources (not shown). Unreacted gases and gaseous reaction by-products exit the reaction chamber 420 through an exhaust line 412. The reaction chamber 420 may optionally be equipped with a purge line (not shown) and/or a pump line (not shown) coupled to a vacuum pump (not shown) so that the reaction chamber 420 may be purged between the various reaction cycles. An RF generator 413 and a corresponding matching unit (not shown) are (electrically) connected to the showerhead 407, allowing for the showerhead 407 to be biased relative to an ion trap, to form a first plasma and/or a second plasma (please refer to the first plasma and the second plasma of method 100, respective) discharge between the showerhead 407 and the ion trap 409. The ion trap 409 is positioned between the showerhead 407 and the susceptor 411 to separate the reaction chamber 420 into an upper chamber 421 and a lower chamber 422. The upper chamber 421 is between the showerhead 407 and the ion trap 409, and the lower chamber 422 is between the ion trap 409 and the susceptor 411. The ion trap 409 restricts the first plasma and/or the second plasma to the upper chamber 421, above the ion trap 409. For example, an electrically grounded mesh plate may be used as an ion trap 409. In some embodiments, the mesh plate is a metal plate (such as aluminum) including hundreds of holes in a showerhead-like pattern that lets radical species pass through to the substrate 410 while trapping the ions. For instance, the mesh plate may comprise between about 1,000 to about 5,000 holes, each hole having a diameter between about 0.5 mm to about 2 mm. The addition of the ion trap 409, beneficially reduces or even eliminates interactions of electrons and ions with the surface of the substrate 410 by restricting the first plasma and/or the second plasma to the upper chamber 421. The semiconductor processing apparatus 400 also includes a controller 414 operably connected to a first valve 415, a second valve 416, and a third valve 417, the RF generator 413, and other components (not shown).

The controller 414 is configured and programmed to independently control (e.g., turn on and off, etc.) the supply of the various gases (e.g., carrier gas, precursor, reactant, and any dilutant, process, feed, and/or purging gases etc.) and the RF generator 413, as required, to deposit a film on the surface of the substrate 410. In some embodiments, the controller 414 is configured to control the first valve 415 to flow the carrier gas from the carrier gas source 402 into the reaction chamber 420. The controller 414 is further configured to open the second valve 416 to flow the precursor from the precursor source 403 into the reaction chamber 420 and to turn on the RF generator 413 to form the first plasma. Turning on the RF generator 413 and opening the second valve 416 may be done one after the other, or simultaneously. After a set period of time, the controller 414 closes the second valve 416 to the precursor source 403 and turns off the RF generator 413. Next, the controller 414 opens the third valve 417 to flow the reactant from the reactant source 404 into the reaction chamber 420 and to turn on the RF generator 413 to form the second plasma. Turning on the RF generator 413 and opening the third valve 417 may be done one after the other, or simultaneously. After a set period of time, the controller 414 closes the third valve 417 to the reactant source 404 and turns off the RF generator 413. The controller 414 is programed to repeat the various process steps to grow a film on the surface of the substrate 410. The controller 414 may be programed to perform other process steps in between these various steps.

In another embodiment, the controller 414 is configured to open the first valve 415 to flow the carrier gas from the carrier gas source 402 into the reaction chamber 420, then open the second valve 416 to flow the precursor from the precursor source 403 into the reaction chamber 420 while turning on the RF generator 413 to form the first plasma. Turning on the RF generator 413 and opening the second valve 416 may be done one after the other, or simultaneously. After a set period of time, the controller 414 closes the second valve 416 to the precursor source 403 and turns off the RF generator 413. Next, the controller 414 opens the third valve 417 to flow the reactant from the reactant source 404 into the reaction chamber 420. After another set period of time, the controller 414 closes the third valve 417 to the reactant source 404. The controller 414 is programed to repeat the various process steps to grow a film on the surface of the substrate 410. The controller 414 may be programed to perform other process steps in between these various steps.

Through the semiconductor processing apparatus 400, the precursor and the reactant are deposited on the substrate 510 via RE-ALD process.

Please refer to FIG. 5, FIG. 5 is a schematic view of a semiconductor processing apparatus 500 according to some embodiments of the present disclosure. The semiconductor processing apparatus 500 is an implementation of method 300. Therefore, the element and/or component describe herein can be connected to method 300.

A carrier gas is supplied from a carrier gas source 502 through a gas manifold 501 into the reaction chamber 520. The carrier gas flows through a showerhead 507 that is positioned directly above a susceptor 511 on which a substrate (i.e., a wafer) 510 is placed. A precursor is also supplied from a precursor source 503, in the form of a gas, through the gas manifold 501 into the reaction chamber 520 through the showerhead 507. The precursor many be vaporized and entrained in or pulsed into the carrier gas. A reactant is supplied from a reactant source 504, in the form of a gas, through the gas manifold 501 into the reaction chamber 520 through the showerhead 507. The semiconductor processing apparatus 500 is also configured to allow for the introduction of other gases, such as other reactant (reactive gas) and other gases (e.g., other carrier gases, precursors or reactive gases, carrier, dilutant, process, feed, and/or purging gases), either through the showerhead 507 or from other ports (not shown) into the reaction chamber 520. Thus, the semiconductor processing apparatus 500 may include other sources (not shown). Unreacted gases and gaseous reaction by-products exit the reaction chamber 520 through an exhaust line 512. The reaction chamber 520 may optionally be equipped with a purge line (not shown) and/or a pump line (not shown) coupled to a vacuum pump (not shown) so that the reaction chamber 520 may be purged between the various reaction cycles. A first RF generator 513 and a corresponding matching unit (not shown) are (electrically) connected to the showerhead 507, allowing for the showerhead 507 to be biased relative to an ion trap 509, to form a first plasma (please refer to the first plasma of method 300) discharge between the showerhead 507 and the ion trap 509. The ion trap 509 is positioned between the showerhead 507 and the susceptor 511 to separate the reaction chamber 520 into an upper chamber 521 and an lower chamber 522. The upper chamber 521 is between the showerhead 507 and the ion trap 509, and the lower chamber 522 is between the ion trap 509 and the susceptor 511. The ion trap 509 restricts the first plasma to the upper chamber 521, above the ion trap 509. For example, an electrically grounded mesh plate may be used as an ion trap 509. In some embodiments, the mesh plate is a metal plate (such as aluminum) including hundreds of holes in a showerhead-like pattern that lets radical species pass through to the substrate 510 while trapping the ions. For instance, the mesh plate may comprise between about 1,000 to about 5,000 holes, each hole having a diameter between about 0.5 mm to about 2 mm. The addition of the ion trap 509, beneficially reduces or even eliminates interactions of electrons and ions with the surface of the substrate 510 by restricting the first plasma to the upper chamber 521. A second RF generator 523, which is a separated RF generator from the first RF generator 513, and a corresponding matching unit (not shown) are (electrically) connected to the susceptor 511, allowing for the susceptor 511 to be biased relative to the ion trap 509, to form a second plasma (please refer to the second plasma of method 300) discharge between the susceptor 511 and the ion trap 509. The ion trap 509 restricts the second plasma to the lower chamber 522, below the ion trap 509. The semiconductor processing apparatus 500 also includes a controller 514 operably connected to a first valve 515, a second valve 516, and a third valve 517, the first RF generator 513, the second RF generator 523, and other components (not shown).

The controller 514 is configured and programmed to independently control (e.g., turn on and off, etc.) the supply of the various gases (e.g., carrier gas, precursor, reactant, and any dilutant, process, feed, and/or purging gases etc.), the first RF generator 513, the second RF generator 523, as required, to deposit a film on the surface of the substrate 510. In some embodiments, the controller 514 is configured to control the first valve 515 to flow the carrier gas from the carrier gas source 502 into the reaction chamber 520. The controller 514 is further configured to open the second valve 516 to flow the precursor from the precursor source 503 into the reaction chamber 520 and to turn on the first RF generator 513 to form the first plasma. Turning on the first RF generator 513 and opening the second valve 516 may be done one after the other, or simultaneously. After a set period of time, the controller 514 closes the second valve 516 to the precursor source 503 and turns off the first RF generator 513. Next, the controller 514 opens the third valve 517 to flow the reactant from the reactant source 504 into the reaction chamber 520 and to turn on the second RF generator 523 to form the second plasma. Turning on the second RF generator 523 and opening the third valve 517 may be done one after the other, or simultaneously. After a set period of time, the controller 514 closes the third valve 517 to the reactant source 504 and turns off the second RF generator 523. The controller 514 is programed to repeat the various process steps to grow a film on the surface of the substrate 510. The controller 514 may be programed to perform other process steps in between these various steps.

Through the semiconductor processing apparatus 500, the precursor is deposited on the substrate 510 via RE-ALD process, and the reactant is deposited on the substrate 510 via PE-ALD process.

Activating silazane precursor molecules through a partial breakdown via the first plasma enables the conformal deposition of SiCN and SiOCN, which has been challenging to do using conventional plasma processing. The film material elemental composition can be controlled with the choice of precursor chemical and the radical treatment during the process. Due to the lack of ion bombardment on the substrate, it is easier to retain sensitive elements like carbon in the film.

The plasma can be ignited in the upper chamber or lower chamber as desired. This allows the design of processes utilizing RE-ALD, PE-ALD, or a combination of the two. Having two RF generators brings a lot of process flexibility to the apparatus. The apparatus allows faster processing, combining pulsed and constant plasma, as well as igniting both plasma zones at the same time for creating a radical-rich plasma flux on the substrate. For example, plasma exposure could be used for inhibiting growth on the top surface of high aspect ratio structures, or radical treatment could be used to adjust the elemental composition of film deposited with direct plasma. Thus, it would be beneficial to have hardware that is capable of doing this in a single deposition chamber. Having two RF generators and matching units ensures that there is no need for plasma tuning or adjustments during processing, resulting in stable plasma generation. The showerhead and susceptor also both have enough surface area on their backsides to ensure a good, noise-free contact for the RF energy.

The semiconductor processing apparatus or system disclosed herein can include additional sources and additional components, which are not shown in FIG. 4 and FIG. 5, such as those typically found on semiconductor processing apparatus. For example, the semiconductor processing apparatus may be provided with one or more heaters and one or more temperature regulators to activate the reactions by elevating the temperature of one or more of the substrates and/or gases entering into the reaction chamber (e.g., carrier gas, precursor, reactive gas, etc.). The semiconductor processing apparatus may also be provided with a pumping system for purging the reaction chamber in between the various processing steps.

The reaction chamber can form part of an ALD assembly and may be a single wafer reactor or it may comprise one or more multi-station deposition chambers. Alternatively, the reactor may be a batch reactor. The various steps of the method can be performed within a single reaction chamber, or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including a reaction chamber can be provided with a heater to activate the reactions by elevating the temperature of one or more of the substrate, the reactants, the precursors, and other gasses. The reactants, precursors, and other gasses may be introduced into the chamber using a showerhead-type reaction chamber or cross-flow reaction chamber, or a combination thereof.

The above discussion has been provided for purposes of illustration using sub-cycles and cycles. The illustrated sub-cycles and cycles are sufficient to explain the disclosed method, but the skilled artisan will appreciate that the principles and advantages of the embodiments taught herein can be readily extended to more complex ALD processes. The skilled artisan will readily appreciate that each cycle can include additional steps (e.g., a second reactant pulse, third reactant pulse, etc., can be introduced), or of the same reactants, and that not all cycles need to be identical (e.g., a second reactant can be introduced every five cycles to incorporate a desired percentage of different elements). Such flexibility is provided and allows for a variety of films to be produced without departing from the spirit of the disclosure.

The methods and systems disclosed herein may be used to deposit a number of films, such as, by way of non-limiting example, silicon (Si) containing films and boron (B) containing films as well as metal containing films, metal oxide containing films, and metal nitride containing films such as films comprising aluminum (Al), molybdenum (Mo), titanium (Ti), hafnium (Hf), tungsten (W), magnesium (Mg), tantalum (Ta), strontium (Sr), and the like. The methods and systems disclosed herein may be used to increase the reactivity of certain precursors such as, by way of non-limiting example, silicon-containing precursors, boron-containing precursors, and metal containing precursors, such as those precursors comprising aluminum, molybdenum, titanium, hafnium, tungsten, magnesium, tantalum, strontium, and the like. The precursor, and the radicalized precursor formed therefrom, may comprise one or more of silicon, boron, and a metal selected from the group consisting of aluminum, molybdenum, titanium, hafnium, tungsten, magnesium, tantalum, and strontium. Suitable precursors may include those which are known to be useful in CVD process. In some embodiments, the precursor may be useful in CVD-type deposition processes, but it may be unreactive in ALD-type deposition processes. In such a case, radicalization of the precursor makes it reactive in ALD-type deposition processes.

The methods and systems disclosed herein may be used to deposit silicon (Si) containing films, such as, by way of non-limiting example, low dielectric constant (k) films, high k gate silicates, low temperature silicon epitaxial films, and films comprising silicon nitride, silicon oxynitride, silicon oxycarbonitride, silicon carbonitride, silicon carbide, silicon oxycarbide, and silicon oxide. In some embodiments, the Si-containing film is selected from the group consisting of silicon nitride, silicon oxynitride, silicon oxycarbonitride, silicon carbonitride, silicon carbide, silicon oxycarbide, silicon oxide, and combinations thereof. In some embodiments, the Si-containing film is selected from the group consisting of silicon oxycarbonitride, silicon carbonitride, and combinations thereof. In these embodiments, the precursor, and hence the radicalized precursor formed therefrom, comprises silicon. In some embodiments, the precursor comprises silicon and may further comprise one more of carbon (C), hydrogen (H), nitrogen (N), oxygen (O), and halogen (X, where X may be a fluorene (F), chlorine (Cl), bromine (Br) or iodine (I)). The silicon-containing precursor may comprise one or more Si—C bond(s), Si—H bond(s), Si—N bond(s), Si—O bond(s), and Si—X bond(s). Suitable silicon-containing precursors may be selected from a silane, a halosilane, an aminosilane, a silicon alkoxide, a siloxane, and combinations thereof. In some embodiments, the silicon-containing precursor is a silane. A silane contains silicon and hydrogen and may optionally also comprise one or more carbon, oxygen, nitrogen, and halogen atoms. Examples of silanes include monosilanes (SiH₄₋ₙ(R)ₙ, where n is an integer from 0 to 4), disilanes (S₂H₆₋ₙ(R)ₙ, where n is an integer from 0 to 6), and trisilane (S₃H₈₋ₙ(R)ₙ, where n is an integer from 0 to 8) and so on, where each R is an independently selected substituent, preferably an alkyl group or aryl group. Examples of suitable silane precursors are silane (SiH₄), disilane (Si₂H₆), and organo silanes such as dimethylsilane (H₂Si(CH₃)₂), diethylsilane (H₂Si(C₂H₅)₂), trimethylsilane (HSi(CH₃)₃), triethylsilane (HSi(C₂H₅)₃), and the like. In some embodiments, the silicon-containing precursor is a halosilane. A halosilane contains at least one halogen atom bonded to a silicon atom (Si—X) and may also optionally comprise one or more hydrogen, carbon, oxygen, and nitrogen atoms. Examples of halosilanes include halosilanes, halodisilanes (Si—Si), halotrisilane (Si—Si—Si), and so on. Examples of suitable halosilane precursors are dichlorosilane (SiH₂Cl₂), dibromosilane (SiH₂Br₂), diiodosilane (SiH₂I₂), hexachlorodisilane (Si₂Cl₆), octachlorotrisilane (Si₃Cl₈), and the like. In some embodiments, the silicon-containing precursor is an aminosilane. An aminosilane (or silylamine) includes at least one nitrogen atom bonded to a silicon atom (Si—N) and carbon and/or hydrogen and may also optionally comprise one or more oxygen and halogen atoms. Examples of aminosilanes include mono-, di-, tri- and tetra-aminosilanes (e.g., H₃Si(NH₂), H₂Si(NH₂)₂, HSi(NH₂)₃, and Si(NH₂)₄, respectively), silazanes (e.g., NH(SiH₃)₂) and trisilylamines (e.g., N(SiH₃)₂)) as well as substituted linear and cyclic derivatives thereof wherein one or more hydrogen atom on the amino group and/or the silane group are independently substituted with a substituent group (R), preferably an alkyl group or aryl group. Examples of aminosilane precursors are bis(diethylamino)silane (CH₈N₂₀Si), di-isopropylaminosilane (C₆H₁₇NSi), N-(diethylaminosilyl)-N-ethylethanamine (C₈H₂₂N₂Si), hexamethyldisilazane ([(CH₃)₃Si]₂NH), hexamethylcyclotrisilazane (C₆H₂₁N₃Si₃), perhydropolysilazane ([SiH₂NH]ₙ), and the like. In some embodiments, the silicon-containing precursor is a silicon alkoxide. A silicon alkoxide includes at least one Si—O—C linkage may also optionally comprise one or more hydrogen, nitrogen, and halogen atoms. Examples of silicon alkoxide include mono-, di-, tri- and tetra-silicon alkoxide (e.g., H₃SiOCH₃), H₂Si(OCH₃)₂, HSi(OCH₃)₃, and Si(OCH₃)₄, respectively) as well as substituted linear and cyclic derivatives thereof wherein one or more hydrogen atoms on the methyl group and/or the silane group are independently substituted with a substituent group (R), prefer an alkyl group or an aryl group. Examples of silicon alkoxide precursors are tetraethylorthosilicate (TEOS, Si(OC₂H₅)₄), dimethoxydimethylsilane (Si(OCH₃)₂(CH₃)₂), trimethoxymethylsilane (Si(OCH₃)₃CH₃), and the like. In some embodiments, the silicon-containing precursor is a siloxane. A siloxane includes at least one Si—O—Si linkage, and may optionally also contain one or more hydrogen, carbon, and halogen atoms. Examples of siloxane include linear and cyclic siloxanes, such as cyclotrisiloxanes, cyclotetrasiloxanes, and silsesquioxanes. Examples of suitable siloxane precursors are include octamethylcyclotetrasiloxane (OMCTS, C₈H₂₄O₄Si₄), 1,1,3,5,5,7-hexamethylcyclotetrasiloxane (HMCTS, C₈H₂₄O₃Si₄), 1,3,5,7-tetramethylcyclotetrasiloxane (TMCTS, C₄H₁₆O₄Si₄), and the like. In some embodiments, the silicon containing precursors is selected from the group consisting of dimethylsilane, diethylsilane, trimethylsilane, triethylsilane, dichlorosilane, diiodosilane, hexachlorodisilane, octachlorotrisilane, bis(dimethylamino)silane, bis(diethylamino)silane, diisopropylaminosilane, N-(diethylaminosilyl)-N-ethylethanamine, hexamethylcyclotrisilazane, tetraethylotrhosilicate, dimethoxydimethylsilane, trimethoxymethylsilane, octamethylcyclotetrasiloxane, 1,1,3,5,5,7-hexamethylcyclotetrasiloxane, 1,3,5,7-tetramethylcyclotetrasiloxane, and combinations thereof.

The methods and systems disclosed herein may be used to deposit boron (B) containing films, such as, by way of non-limiting example, hard masks, low dielectrics, lining layers, boron-doped films (e.g., borosilicate glass), and films comprising boron nitride, boron carbide, borocarbonitride, and boron oxide. In some embodiments, the boron-containing film is selected from the group consisting of boron nitride, boron carbide, borocarbonitride, boron oxide, and combinations thereof. In some embodiments, the boron-containing film is amorphous boron nitride. In these embodiments, the precursor, and the radicalized precursor formed therefrom, comprises boron. In some embodiments, the precursor comprises boron and may further comprise one more of carbon (C), hydrogen (H), nitrogen (N), and oxygen (O). The boron-containing precursor may comprise one or more B—C bond(s), B—H bond(s), B—N bond(s), and B—O bond(s). In some embodiments, the boron-containing precursor consists of boron and a halogen. The halogen may be selected from a group consisting of fluorine (F), chlorine (Cl), bromine (Br) and iodine (I). In some embodiments, the halogen is selected from a group consisting of chlorine (Cl), bromine (Br) and iodine (I). In some embodiments, the halogen is selected from a group consisting of chlorine (Cl), and bromine (Br). In some embodiments, the boron-containing precursor consists of boron and a halogen. In some embodiments, the boron-containing precursor is selected from a group consisting of boron trihalides. In some embodiments, the boron-containing precursor comprises BCl₃. In some embodiments, the boron-containing precursor comprises BBr₃

Further suitable boron-containing precursors may be selected from a borane, an alkyl borane, an aryl borane, a carbborane, an amine or amino borane, a borate ester, a borazine, and a combination thereof. In some embodiments, the boron-containing precursor is a borane (BₓH_{Y}). Examples of suitable borane precursors are diborane (B₂H₆), tetraborane (B₄H₁₀), pentaborane (B₅H₉), decaborane (B₁₀H₁₄), octadecaborane (B₁₈H₂₂), and the like. In some embodiments, the borane precursor is substituted with one or more alkyl group(s), aryl group(s), and combinations thereof For example, one or more hydrogen atoms in a borane may be substituted with an alkyl group and/or an aryl group. Examples of suitable alkyl and aryl borane precursors include trimethyl borane (B(CH₃)₃), triethyl borane (B(C₂H₅)₃), triphenyl borane (B(C₆H₅)₃), and the like. In some embodiments, the boron-containing precursor is a carborane. A carborane contains boron, carbon, and hydrogen and may optionally be substituted with one or more oxygen, nitrogen, and halogen atoms. Examples of suitable carborane precursors are nido-carborane (C₂B₄H₈), ortho-carborane (C₂B₁₀H₁₂), and the like. In some embodiments, the boron-containing precursor is an amine or amino borane. Examples of amine boranes include ammonia borane (NH₃BH₃) and substituted derivatives thereof (e.g., NRₙH₃₋ₙBH₃, where n is an integer from 1 to 3 and each R is independently a substituent group, preferably an alkyl group or an aryl group). Examples of amino boranes include mono-, di-, tri-amino borane (e.g., H₂B(NH₂), HB(NH₂)₂, and B(NH₂)₃, respectfully) and linear and cyclic substituted derivatives thereof (e.g., H₂B(NHR), H₂B(NR₂), HB(NHR)₂, HB(NR₂)₂, B(NHR)₃, and B(NR₂)₃, where each R is independently a substituent group, preferably an alkyl group or an aryl group). Examples of suitable amine and amino borane precursors are ammonia borane (NH₃BH₃), methylamine borane (CH₃NH₂BH₃), dimethylamine borane ((CH₃)₂NHBH₃), trimethylamine borane ((CH₃)₃NBH₃), t-butylamine borane ((CH₃)₃CNH₂BH₃), tris(dimethylamino)borane (B(N(CH₃)₂)₃), B(cycloriborazanyl)amine borane (B₄N₄H₁₆), and the like. In some embodiments, the boron-containing precursor is a borate ester. Examples of borate esters include ortho borates such as boronic esters (BR₂(OR)), boronic esters (BR₂(OR)), and borates (B(OR)₃) and metaborates (B₃O₃(OR)₃), where each R is independently a substituent group, preferably an alkyl group or an aryl group. Examples of suitable borate ester precursors are trimethyl borate (B(OCH₃)₃), triethyl borate (B(OCH₂CH₃)₃), and the like. In some embodiments, the boron-containing precursor is borazine or a substituted borazine. Borazine has the chemical structure B₃H₆N₃. In substituted borazines one or more H atoms are replaced with a substituent group (R), preferably an alkyl group or an aryl group. Additionally, or alternatively, one or more boron or nitrogen atoms in the borazine ring may be substituted with a carbon atom. Examples of suitable borazine precursors are borazine (B₃H₆N₃), 2,4,6-trichloroborazine (B₃H₃Cl₃N₃), 2,4,6-tribromoborazine (B₃H₃Br₃N₃), and the like. In some embodiments, the boron containing precursor is selected from the group consisting of nido-carborane, ortho-carborane, ammonia borane, dimethylamine borane, trimethylamine borane, t-butylamine borane, tris(dimethylamino)borane, B(cycloriborazanyl)amine borane, trimethyl borate, triethyl borate, borazine, 2,4,6-trichloroborazine, 2,4,6-tribromoborazine, diborazine, and combinations thereof.

In some embodiments, the reactive gas may be an oxygen containing gas. For example, the oxygen containing gas may be selected from one or more of oxygen (O₂), ozone (O₃), water (H₂O), hydrogen peroxide (H₂O₂), an alcohol (ROH, where R is an alkyl or aryl group) such as methanol (CH₃OH) and ethanol (C₂H₅OH), nitrogen dioxide (NO₂), nitrous oxide (N₂O), and oxygen atoms (O*) created in a plasma. In some embodiments, the reactive gas may be a nitrogen containing gas. For example, the nitrogen containing gas may be selected from one or more of ammonia (NH₃), hydrazine (N₂H₄), nitric oxide (NO), and activated nitrogen (N₂), activated ammonia (NH₃), and nitrogen atoms (N*) created in a plasma. In some embodiments, the reactive gas may be selected from one or more of hydrogen (H₂) and hydrogen atoms (H*) created in a plasma. In some embodiments, the reactive gas comprises one or more of O₂, H₂O, NH₃, and H₂. In some embodiments, the reactive gas may comprise O*, N*, H*, and combinations thereof.

The methods and systems disclosed herein can provide several benefits, including enhanced precursor reactivity which may reduce the processing time to obtain a desired film thickness and/or the number of the cycles needed to obtain the desired film thickness. It also may allow for deposition to occur under lower temperature processing conditions. The methods and systems may also improve the uniformity and conformality of the film. Without wishing to be bound by a particular theory, the radicalized precursor is more reactive and it may also be smaller in size compared to the parent precursor from which it is derived; this may result in a higher degree of surface coverage on the substrate, thus leading to faster growth, higher uniformity, and improve conformity, which may occur, for example, on sidewalls of trench structures.

Although embodiments of the present disclosure and their advantages have been described in detail, it should be understood that various changes, substitutions and alterations may be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, the scope of the present disclosure is defined by the scope of the appended claims. In addition, each scope of the claims is constructed as a separate embodiment, and various combinations of the claims and combinations of embodiments are within the scope of the present disclosure.

What is claimed is:

1. A method for forming a film on a surface of a substrate, comprising:
introducing a substrate in a lower chamber of a reaction chamber, wherein the reaction chamber is separated into an upper chamber and the lower chamber using an ion trap;
introducing a first plasma into the upper chamber;
introducing a precursor into the reaction chamber and radicalizing the precursor using the first plasma;
introducing a reactant into the reaction chamber;
introducing a second plasma into the upper chamber to radicalize the reactant.

2. The method as claimed in claim 1, wherein the precursor comprises a silazane.

3. The method as claimed in claim 1, wherein the ion trap is grounded.

4. The method as claimed in claim 1, wherein the precursor and the reactant are introduced into the reaction chamber via a showerhead, and the showerhead is connected to an RF generator to generate the first plasma and the second plasma.

5. The method as claimed in claim 1, further comprising a purge step after introducing a precursor into the reaction chamber, and after introducing a second plasma into the upper chamber.

6. The method as claimed in claim 1, wherein the RF power of the first plasma is lower than the RF power of the second plasma.

7. The method as claimed in claim 1, wherein the RF power of the first plasma is lower than 100 W, and the RF power of the second plasma is higher than 50 W.

8. A method for forming a film on a surface of a substrate, comprising:
providing a reaction chamber having an upper chamber and a lower chamber separated by an ion trap;
introducing a substrate into the lower chamber;
introducing a precursor into the reaction chamber and radicalizing the precursor using a first plasma in the upper chamber to form a radicalized precursor;
introducing a reactant into the reaction chamber and generating a second plasma in the lower chamber to break down the reactant and expose the substrate to various plasma species.

9. The method as claimed in claim 8, wherein the precursor comprises a silazane.

10. The method as claimed in claim 8, further comprising:
purging the reaction chamber between the steps of introducing a precursor and introducing a reactant.

11. The method as claimed in claim 8, further comprising:
repeating the step of introducing a precursor and the step of introducing a reactant.

12. The method as claimed in claim 8,
wherein the precursor and the reactant are introduced into the reaction chamber via a showerhead, and the showerhead is connected to a first RF generator to generate the first plasma,
wherein the substrate is placed on a susceptor, and the susceptor is connected to a second RF generator to generate the second plasma.

13. The method as claimed in claim 8, wherein the RF power of the first plasma is lower than 100 W, and the RF power of the second plasma is lower than 1,500 W.

14. The method as claimed in claim 8, wherein the reactant comprises at least one of hydrogen, nitrogen, oxygen.

15. The method as claimed in claim 8, wherein the RF power of the second plasma is higher than the RF power of the first plasma.

16. A semiconductor processing apparatus, comprising:
a reaction chamber;
a showerhead, located at the upper portion of the reaction chamber;
a susceptor, located at the lower portion of the reaction chamber and supporting a substrate;
an ion trap, located between the showerhead and the susceptor;
a precursor source, for introducing a precursor into the reaction chamber via the showerhead;
a reactant source, for introducing a reactant into the reaction chamber via the showerhead;
a first RF generator, connected to the showerhead and generating a first plasma between the showerhead and the ion trap via the showerhead.

17. The semiconductor processing apparatus as claimed in claim 16, wherein the ion trap is a mesh plate, and the mesh plate is grounded.

18. The semiconductor processing apparatus as claimed in claim 16, further comprising a controller, configured to:
igniting the first plasma between the showerhead and the ion trap;
introducing the precursor into the reaction chamber;
purging the reaction chamber;
introducing the reactant into the reaction chamber;
igniting the second plasma between the ion trap and the susceptor; and
purging the reaction chamber.

19. The semiconductor processing apparatus as claimed in claim 16, further comprising a second RF generator, connected to the susceptor and generating a second plasma between the ion trap and the susceptor via the susceptor.

20. The semiconductor processing apparatus as claimed in claim 19, wherein the first RF generator and the second RF generator are separate RF generators.
